(19) United States
(12) Patent Application Publication
(10) Pub. No.: US 2008/0277738 A1
(43) Pub. Date: Nov. 13, 2008

(54) MEMORY CELLS, MEMORY BANKS, MEMORY ARRAYS, AND ELECTRONIC SYSTEMS

(76) Inventor: Venkat Ananthan, Boise, ID (US)

Correspondence Address: WELLS ST. JOHN P.S., 601 W. FIRST AVENUE, SUITE 1300, SPOKANE, WA, 99201, US

(21) Appl. No.: 11/745,670

(22) Filed: May 8, 2007

(51) Int. Cl. H01L 27/088; H01L 21/336; H01L 29/78; H01L 21/8239

(52) U.S. Cl. 257/390; 257/401; 438/128; 438/284; 257/E27.06; 257/E21.645; 257/E29.255; 257/E21.409

(57) ABSTRACT

Some embodiments include memory cells containing vertical floating bodies, and containing gates which entirely laterally surround the floating bodies. Some embodiments include memory banks which contain multiple memory cells extending from a conductively-doped diffusion region. Some embodiments include memory arrays in which electrically insulative partitions extend through a conductively-doped diffusion region to divide the diffusion region into a plurality of lines, and in which multiple memory cells extend vertically upward from each of such lines. Some embodiments include electronic systems containing processors in data communication with memory, and in which the memory includes an array of zero capacitor one transistor memory cells. Some embodiments include methods of forming vertically-extending memory cells. Some embodiments include methods of forming of banks of memory cells in which all of the memory cells extend to a conductively-doped region. Some embodiments include methods of forming memory arrays.

### TECHNICAL FIELD

Memory Cells, Memory Banks, Memory Arrays, Electronic Systems, Methods of Forming Memory Cells, Methods Of Forming Banks Of Memory Cells, And Methods Of Forming Memory Arrays.

### BACKGROUND

Integrated circuitry may include arrays of memory devices for data storage. The memory devices may, for example, be dynamic random access memory (DRAM) devices; with the DRAM unit cells corresponding to transistors coupled with charge storage devices (typically capacitors).

A continuing goal of integrated circuit fabrication is to increase the level of integration. Corresponding goals may include goals to decrease the size of memory devices, to simplify memory devices, and/or to reduce the complexity and amount of wiring associated with memory devices. Another continuing goal of integrated circuit fabrication is to reduce the number of steps of a fabrication process, thereby improving throughput and possibly reducing costs.

A problem occurring in the scaling of DRAM is in the shrinking of the dimensions of the capacitors. A new type of memory is being developed which lacks the capacitor of DRAM. The new memory may be referred to as zero-capacitor-one-transistor (0C1T) memory, capacitorless memory, or in some instances as ZRAM™ (zero capacitance DRAM), and may be formed to much higher levels of integration than DRAM.

The 0C1T memory utilizes a floating body effect to store data. Specifically, charge stored on the floating body of a transistor device may alter the threshold voltage for the device. Accordingly, the floating body at one charged state may be considered to be at a “0” state, and at another charged state may be considered to be at a “1” state. The particular state of the floating body may be ascertained by determining the threshold voltage of the transistor.

Although 0C1T memory has potential advantages relative to DRAM and other memory structures, there remains a challenge to develop economical methods for forming large arrays of 0C1T memory. Accordingly, it is desired to develop new methods of forming 0C1T memory, and to develop new 0C1T memory structures.

### BRIEF DESCRIPTION OF THE DRAWINGS

FIGS. 1 and 2 are a three-dimensional view and a cross-sectional side view, respectively, of an embodiment of a 0C1T memory unit cell. The cross-section of FIG. 2 is along the line 2-2 of FIG. 1.

FIGS. 3-5 are a top view and a pair of cross-sectional side views of a portion of a semiconductor wafer at a processing stage of an embodiment. The view of FIG. 4 is along the lines 4-4 of FIGS. 3 and 5, and the view of FIG. 5 is along the lines 5-5 of FIGS. 3 and 4.

FIGS. 6-8 are views of the fragments of FIGS. 3-5 at a processing stage subsequent to that of FIGS. 3-5. The view of FIG. 7 is along the lines 7-7 of FIGS. 6 and 8, and the view of FIG. 8 is along the lines 8-8 of FIGS. 6 and 7.

FIGS. 9-11 are views of the fragments of FIGS. 3-5 at a processing stage subsequent to that of FIGS. 6-8. The view of FIG. 10 is along the lines 10-10 of FIGS. 9 and 11, and the view of FIG. 11 is along the lines 11-11 of FIGS. 9 and 10.

FIGS. 12-14 are views of the fragments of FIGS. 3-5 at a processing stage subsequent to that of FIGS. 9-11. The view of FIG. 13 is along the lines 13-13 of FIGS. 12 and 14, and the view of FIG. 14 is along the lines 14-14 of FIGS. 12 and 13.

FIGS. 15-17 are views of the fragments of FIGS. 3-5 at a processing stage subsequent to that of FIGS. 12-14. The view of FIG. 16 is along the lines 16-16 of FIGS. 15 and 17, and the view of FIG. 17 is along the lines 17-17 of FIGS. 15 and 16.

FIGS. 18-20 are views of the fragments of FIGS. 3-5 at a processing stage subsequent to that of FIGS. 15-17. The view of FIG. 19 is along the lines 19-19 of FIGS. 18 and 20, and the view of FIG. 20 is along the lines 20-20 of FIGS. 18 and 19.

FIGS. 21-23 are views of the fragments of FIGS. 3-5 at a processing stage subsequent to that of FIGS. 18-20. The view of FIG. 22 is along the lines 22-22 of FIGS. 21 and 23, and the view of FIG. 23 is along the lines 23-23 of FIGS. 21 and 22.

FIGS. 24-26 are views of the fragments of FIGS. 3-5 at a processing stage subsequent to that of FIGS. 21-23. The view of FIG. 25 is along the lines 25-25 of FIGS. 24 and 26, and the view of FIG. 26 is along the lines 26-26 of FIGS. 24 and 25.

FIGS. 27-29 are views of the fragments of FIGS. 3-5 at a processing stage subsequent to that of FIGS. 24-26. The view of FIG. 28 is along the lines 28-28 of FIGS. 27 and 29, and the view of FIG. 29 is along the lines 29-29 of FIGS. 27 and 28.

FIGS. 30-32 are views of the fragments of FIGS. 3-5 at a processing stage subsequent to that of FIGS. 27-29. The view of FIG. 31 is along the lines 31-31 of FIGS. 30 and 32, and the view of FIG. 32 is along the lines 32-32 of FIGS. 30 and 31.

FIG. 33 is a diagrammatic view of a computer embodiment.

FIG. 34 is a block diagram showing particular features of the motherboard of the FIG. 33 computer embodiment.

FIG. 35 is a high level block diagram of an electronic system embodiment.

FIG. 36 is a simplified block diagram of another electronic system embodiment.

### DETAILED DESCRIPTION OF THE ILLUSTRATED EMBODIMENTS

Silicon-on-insulator (SOI) may be utilized for fabrication of 0C1T memory. However, SOI may be more expensive than bulk semiconductor, and accordingly it would be desirable to develop methods of forming 0C1T memory from bulk semiconductor. Although some embodiments were motivated, at least in part, by a desire to avoid SOI, some embodiments may be alternatively utilized with SOI.

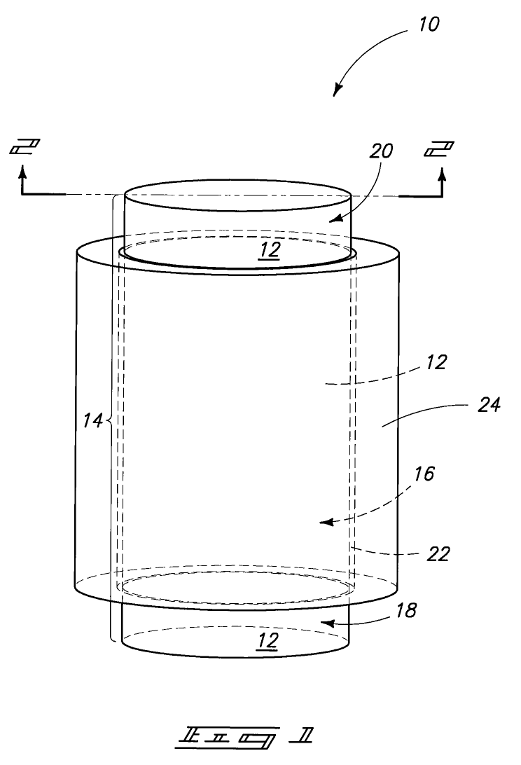

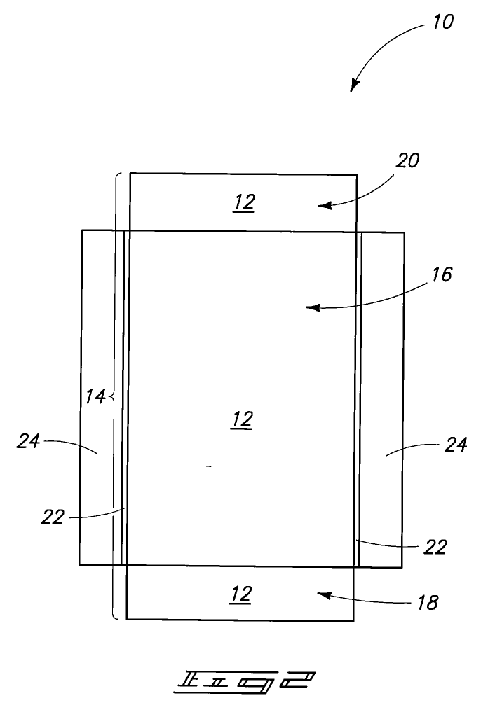

In some embodiments, a 0C1T memory unit cell is formed as a vertical surround gate transistor. An example embodiment of such 0C1T memory unit cell is shown in FIGS. 1 and 2 as a unit cell 10.

The unit cell 10 comprises a semiconductor material 12 forming a projection (or stem) 14 which is subdivided into three regions 16, 18 and 20. The regions 18 and 20 are conductively-doped to the same majority dopant type as one another, and the region 14 is conductively-doped to an opposite majority dopant type as regions 18 and 20. Accordingly, regions 18 and 20 may be majority n-type while region 16 is majority p-type; or regions 18 and 20 may be majority p-type while region 16 is majority n-type. The regions are described as being majority doped to a particular type to indicate that the amount of the particular type of dopant (as measured in atomic percentage) exceeds the amount of any other type of dopant in the regions. A region described as being majority doped with a particular type of dopant may therefore be doped only with the particular dopant, or may be doped with other types of dopants provided that the majority of the dopant in the region is the particular type of dopant. For instance, a region described as being majority n-type doped may comprise some p-type dopant therein, but the amount of n-type dopant exceeds the amount of p-type dopant.

The outer regions 18 and 20 of semiconductor material 12 are source/drain regions of the unit cell, and the central region 16 of the semiconductor material is a floating body region of the unit cell.

The semiconductor material 12 may comprise any suitable semiconductor composition or combination of compositions, and may, for example, comprise, consist essentially of, or consist of silicon. The semiconductor material 12 may be in any suitable phase, and may accordingly be in one or more of amorphous, polycrystalline and monocrystalline forms. In some embodiments, the semiconductor material 12 will comprise, consist essentially of, or consist of monocrystalline silicon.

The semiconductor material 12, either alone or in combination with other portions of the unit cell, may be considered to be a semiconductor substrate or semiconductor construction. The terms “semiconductive substrate,” “semiconductor construction” and “semiconductor substrate” mean any construction comprising semiconductive material, including, but not limited to, bulk semiconductive materials such as a semiconductive wafer (either alone or in assemblies comprising other materials), and semiconductive material layers (either alone or in assemblies comprising other materials). The term “substrate” refers to any supporting structure, including, but not limited to, the semiconductive substrates described above.

The unit cell 10 comprises a dielectric material 22 entirely laterally surrounding at least a portion of the floating body region 16, and comprises an electrically conductive gate material 24 also entirely laterally surrounding at least a portion of the floating body region. The electrically conductive gate material is spaced from the floating body region by the dielectric material.

The dielectric material 22 may comprise any suitable composition or combination of compositions, and may, for example, comprise, consist essentially of, or consist of silicon dioxide and/or various high-k dielectric materials (with high-k dielectric materials being materials having a dielectric constant greater than silicon dioxide, and including, for example, aluminum oxide).

The electrically conductive gate material may comprise any suitable composition or combination of compositions, and may, for example, comprise, consist essentially of, or consist of one or more of various metals (for instance, ruthenium, platinum, titanium, tungsten, etc.); metal-containing compositions (for instance, metal nitrides, metal silicides, etc.); and conductively-doped semiconductor materials (for instance, conductively-doped silicon, germanium, etc.). Example metal nitrides are titanium nitride and tungsten nitride, and example metal silicides are titanium silicide and tungsten silicide.

The dielectric material 22 and conductive gate material 24 are shown exactly overlapping the central region 16 of the semiconductor material. In other embodiments, the dielectric material and conductive gate material may extend partially over one or both of the source/drain regions 18 and 20, and in yet other embodiments the dielectric material and conductive gate material may be restricted to only a portion of the central region 16 so that some of the central region is not overlapped by the dielectric material and conductive gate material. Also, although the conductive gate material is shown exactly overlapping the dielectric material, in other embodiments the dielectric material may cover a wider expanse of the unit cell than the conductive material. For instance, the dielectric material may extend over portions of the source/drain regions 18 and 20, as well as over an entirety of the floating body portion 16, and the conductive gate material may extend only over the floating body portion.

The source/drain regions 18 and 20 may be referred to as electrodes of the unit cell. The 0C1T memory unit cell may be incorporated into a memory array by forming the conductive gate material as part of a wordline, electrically coupling one of the electrodes with a controlled voltage line, and electrically coupling the other of the electrodes to a bitline. For instance, the source may be coupled to a bitline, and the drain coupled to a line controlling voltage to the drain.

The unit cell 10 may be written to, and read from, with any suitable technique. For instance, the unit cell may be programmed using either impact ionization or gate induced drain leakage (GIDL). During the programming, accumulation of majority carriers (holes) in the floating body may be defined as a state “1” and a reduced number of majority carriers may be defined as a state “0”. The number of majority carriers in the “0” state is less than that in the “1” state, which may include, but is not limited to, embodiments in which there are no detectable carriers in the “0” state.

Example methods of reading and writing are as follows. A “1” may be written by utilizing impact ionization to inject holes into the floating body. Alternatively, the conductive gate may be reverse biased relative to the drain to cause GIDL which injects holes into the body (through, for example, band-to-band tunneling). A problem with impact ionization may be that the method can degrade device reliability through hot-carrier injection into gate dielectric. Accordingly, the GIDL-based method may be better for maintaining gate dielectric integrity while enabling high-speed programming. A “0” may be written by forward biasing the drain while applying negative voltage to the source with the bitline, and applying a positive voltage to the gate with the wordline. Such may remove holes stored in the floating body. The condition of the unit cell may be read by biasing the transistor of the unit cell in the linear region. Drain current may be affected by the number of holes accumulated in the body, and accordingly determination of the drain current may enable determination of the state of the unit cell.

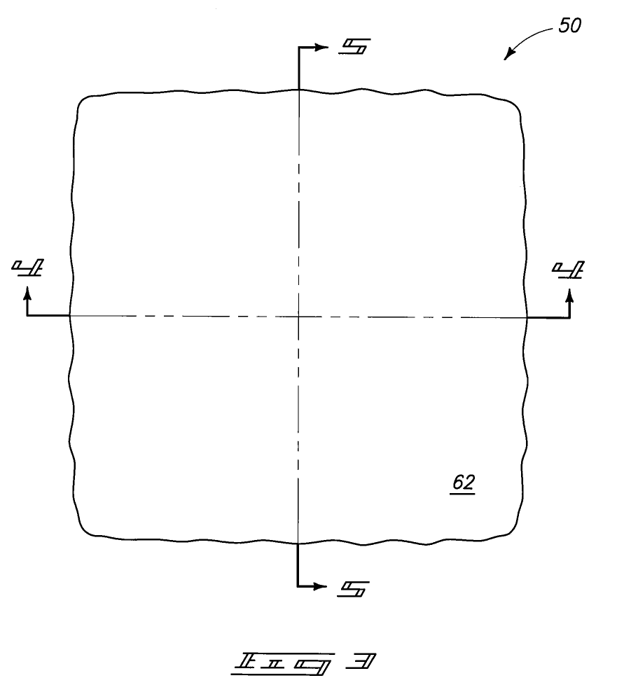

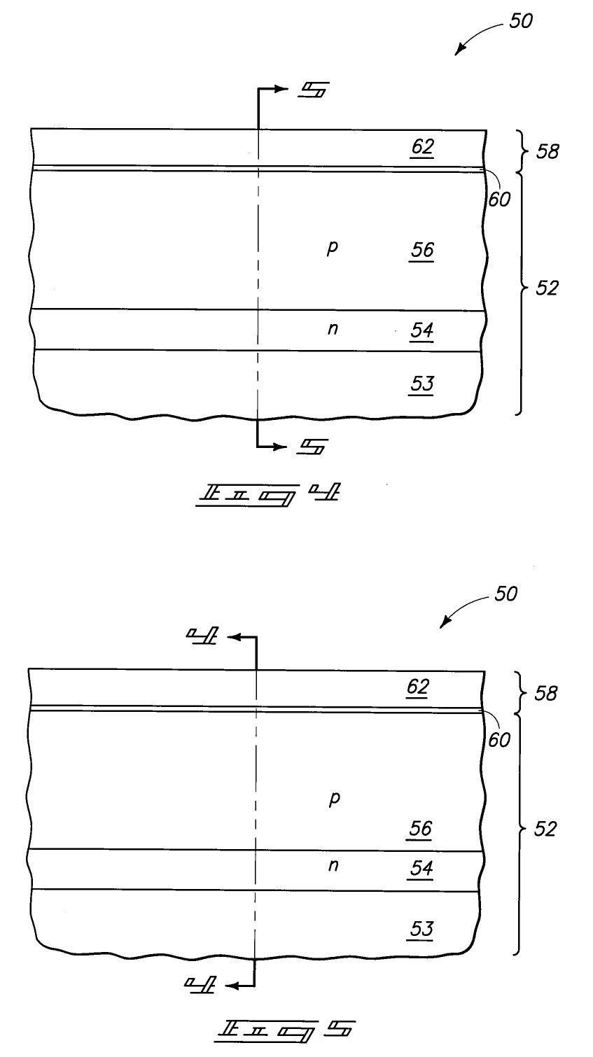

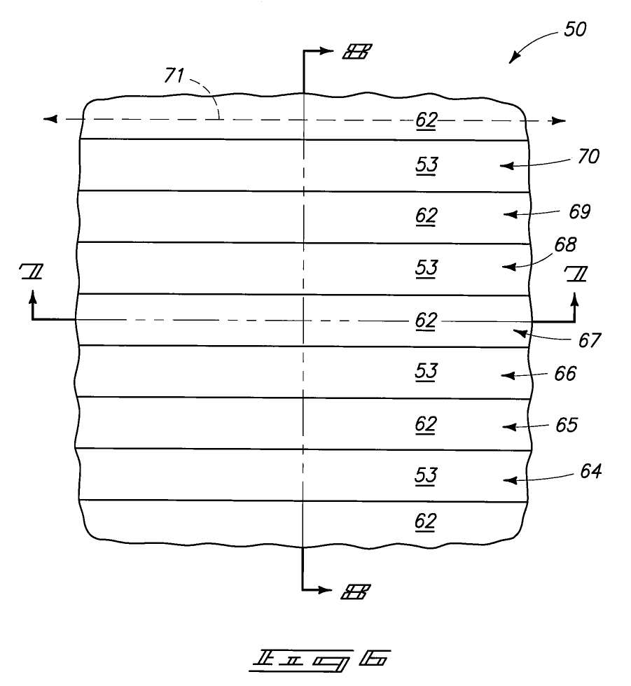

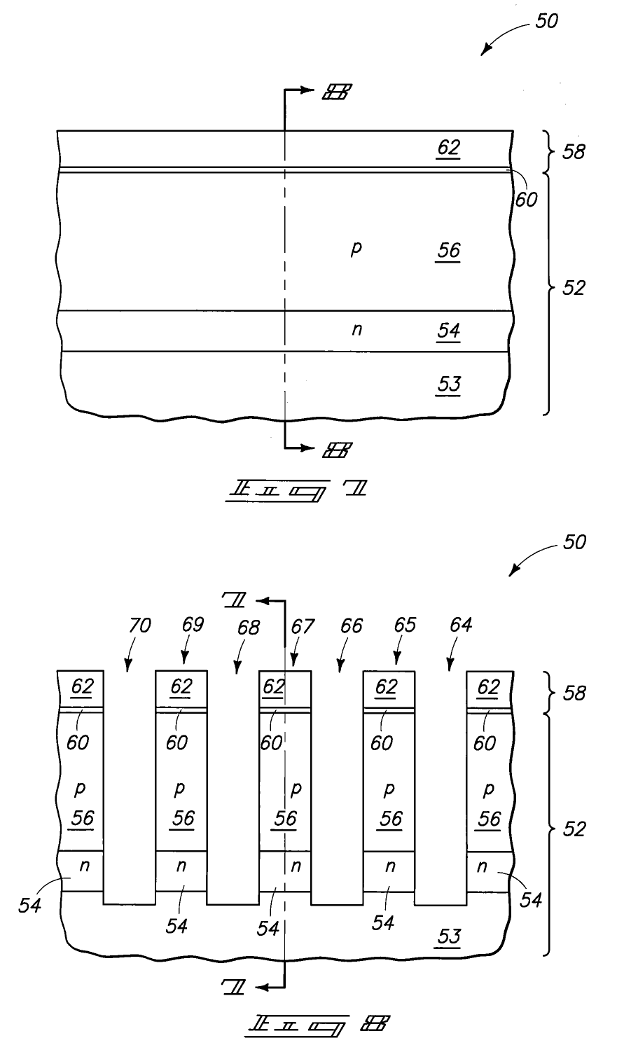

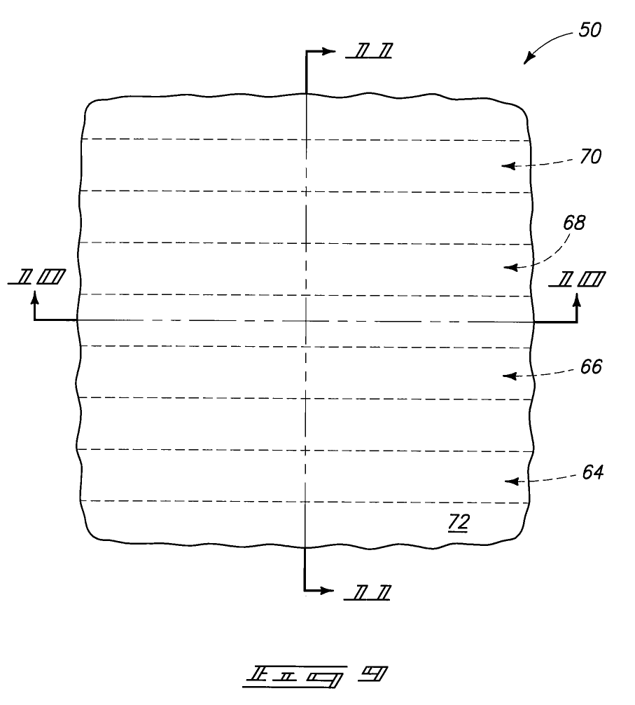

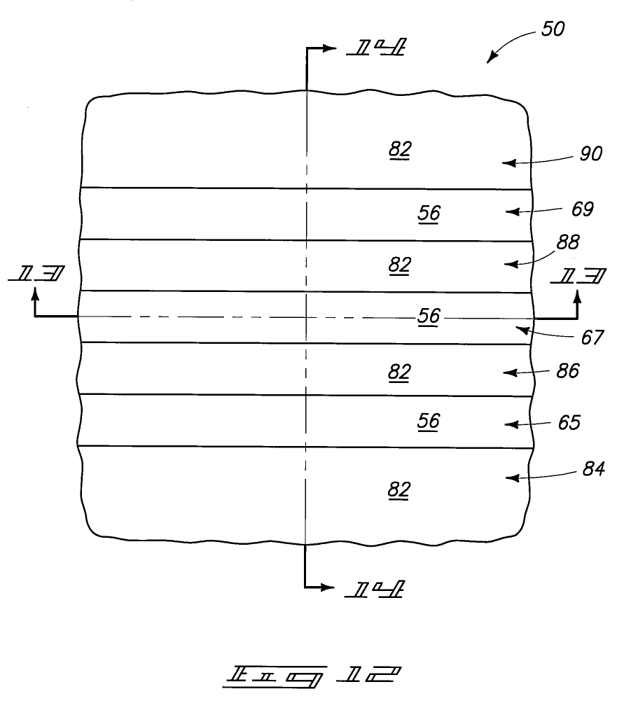

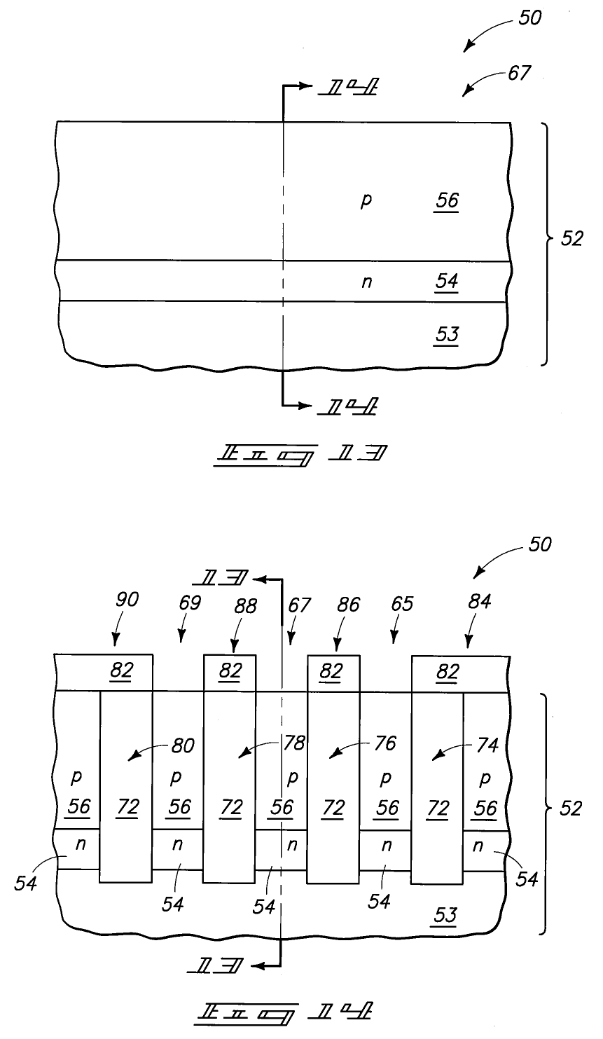

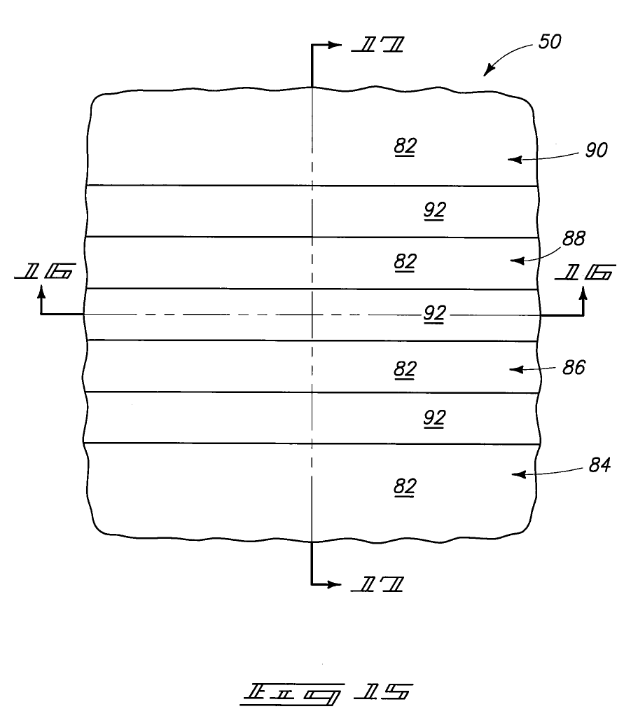

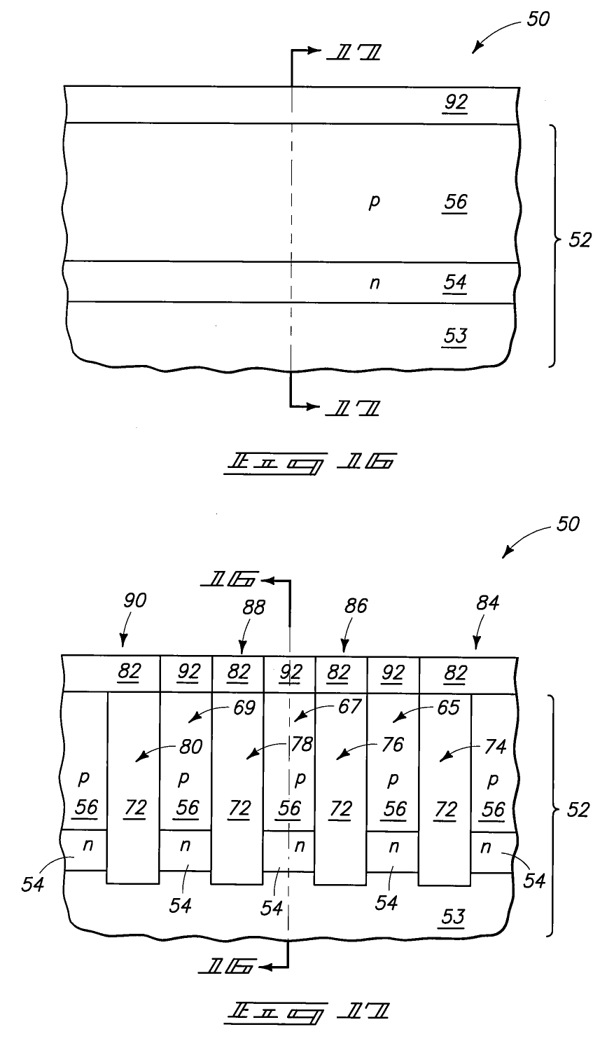

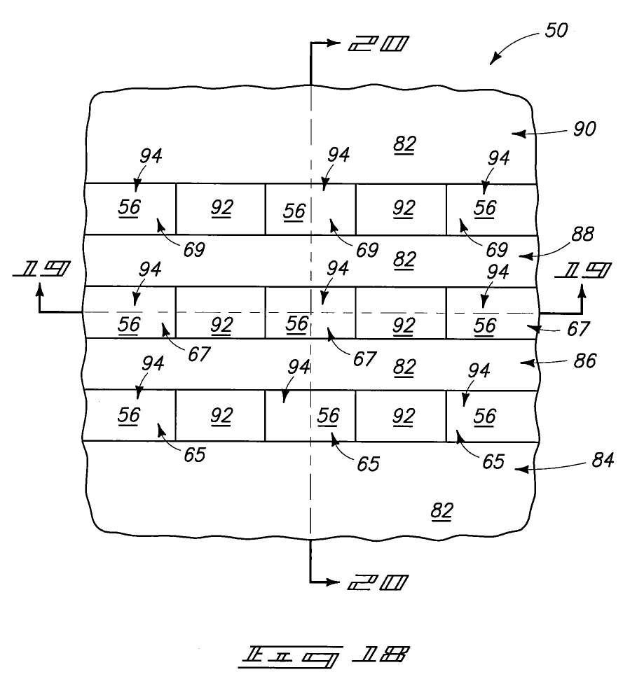

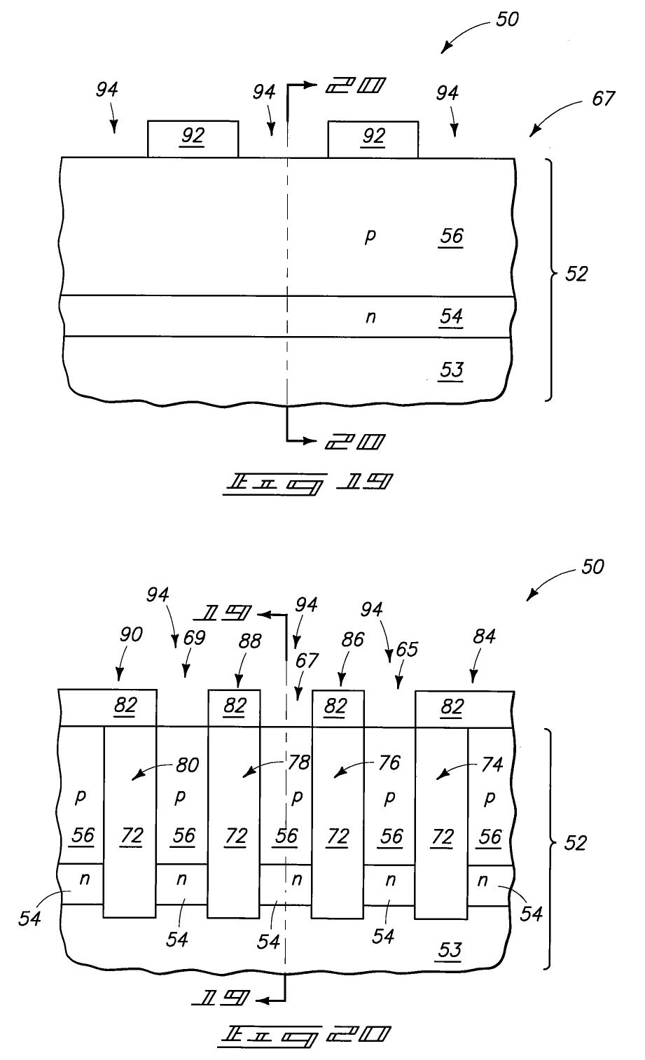

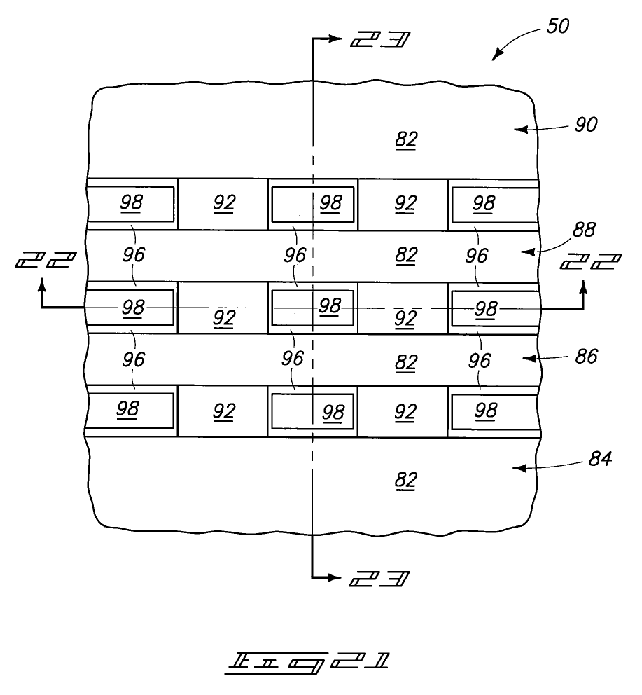

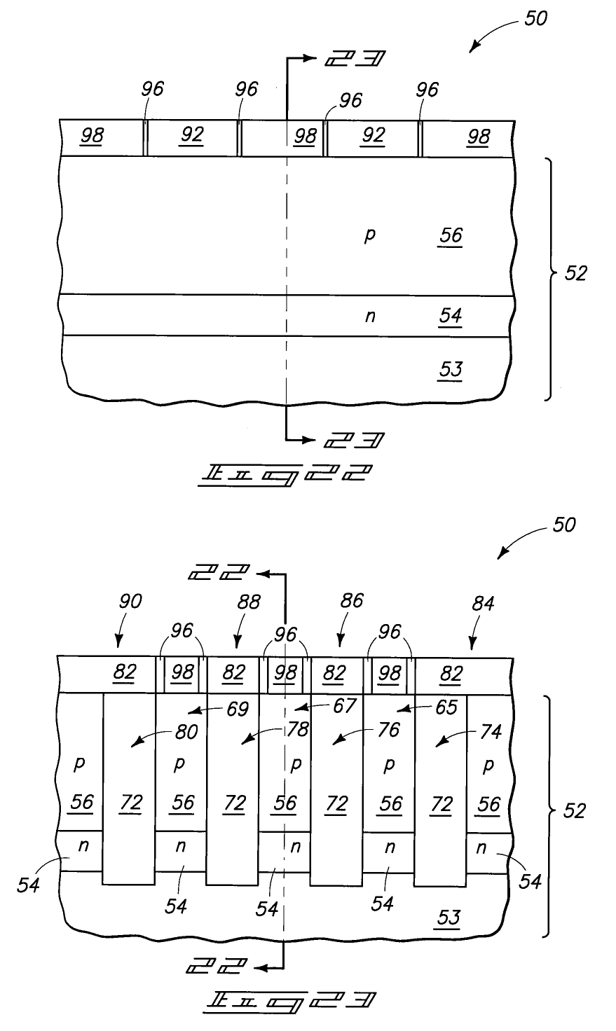

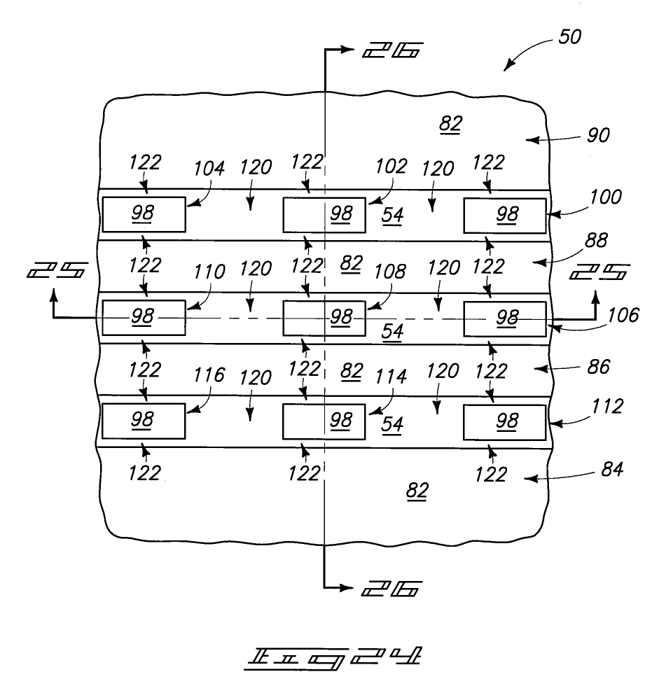

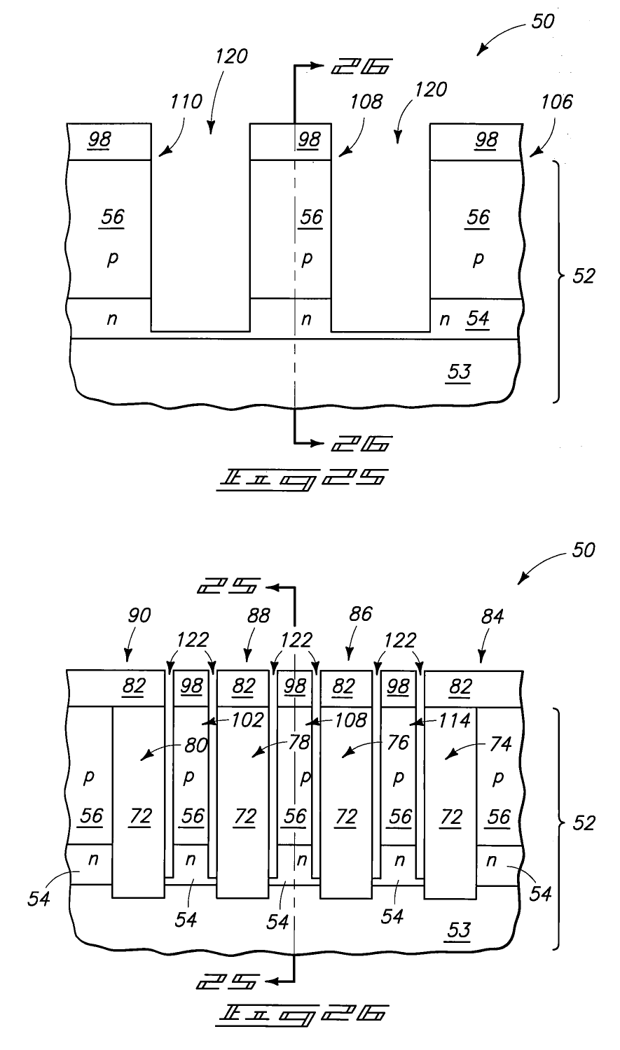

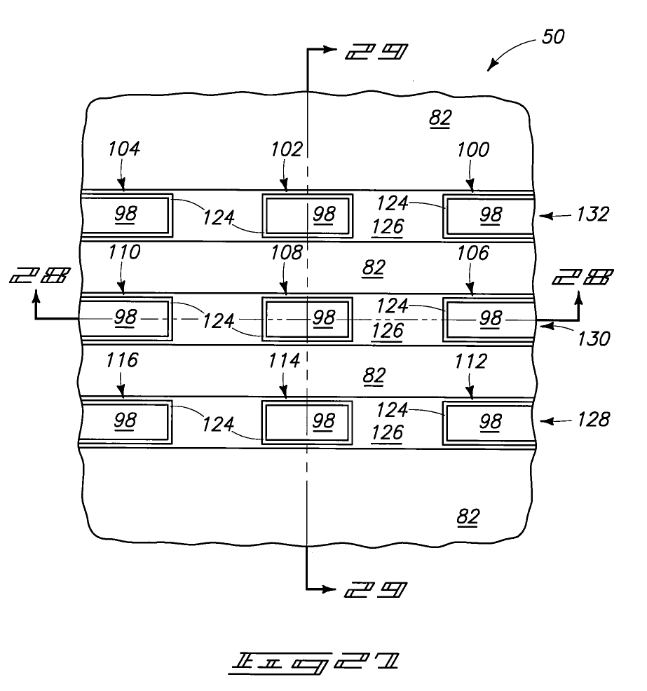

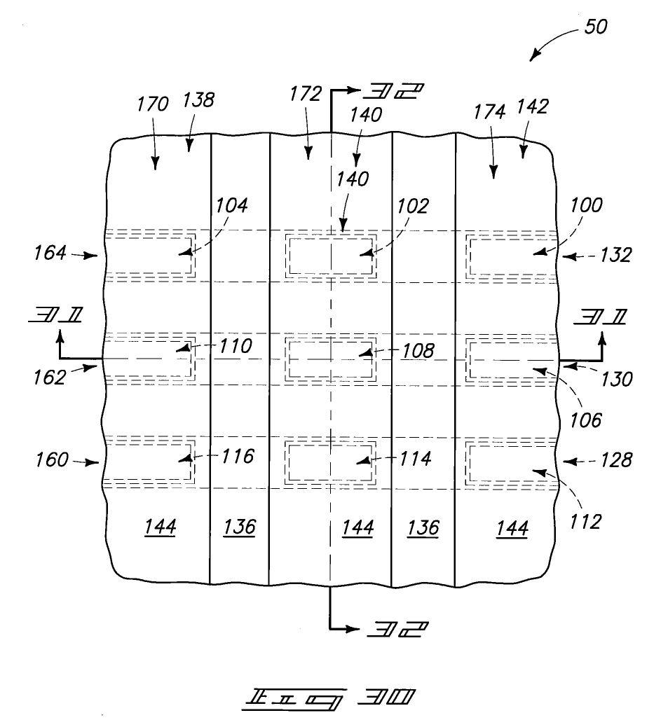

An example method of forming an array of 0C1T memory unit cells is described with reference to FIGS. 3-32.

Referring to FIGS. 3-5, a portion of a semiconductor construction 50 is illustrated. The construction 50 comprises a semiconductor base 52. Such semiconductor base may correspond to bulk silicon of a semiconductor wafer, and accordingly may comprise, consist essentially of, or consist of monocrystalline silicon.

A pair of doped regions 54 and 56 are formed within semiconductor base 52. The regions may be referred to as first and second regions, respectively, with the second region being directly over the first region in the shown embodiment.

A region 53 of the base is beneath doped region 54. The region 53 is shown to be undoped, but may comprise a light amount of background doping (such as background p-type doping).

The doped regions 54 and 56 may be formed by blanket implanting suitable conductivity-enhancing dopant into the semiconductor material of base 52. The region 56 is doped to an opposite conductivity type than the region 54. In the shown embodiment, region 56 is doped to be p-type, and region 54 is doped to be n-type. In other embodiments, the dopant types of regions 54 and 56 may be reversed so that region 56 is majority n-type doped and region 54 is majority p-type doped. The dopant levels in regions 54 and 56 may be sufficient to make the regions electrically conductive. Region 54 ultimately forms electrodes (number 18 and 20 of FIG. 1) of 0C1T memory cells, and region 56 ultimately forms floating bodies (region 16 of FIG. 1) of the 0C1T memory cells. In some embodiments semiconductor base 52 may be initially p-type doped, and then region 54 may be formed by counter-doping a segment of the base.

Masking material 58 is formed over semiconductor base 52. The shown masking material comprises two layers 60 and 62. Layer 60 may comprise, consist essentially of, or consist of silicon dioxide, and may be referred to as a pad oxide. Layer 62 may comprise, consist essentially of, or consist of silicon nitride. The pad oxide protects an upper surface of semiconductor base 52 from stress that may be induced if a nitride-containing layer is placed directly against such upper surface.

Referring to FIGS. 6-8, a plurality of trenches 64, 66, 68 and 70 are formed to extend through doped regions 54 and 56. The trenches may be formed by initially patterning masking material 58 with a photolithographically-formed mask (not shown) to form a hard mask from layers 60 and 62. Subsequently, the pattern from the hard mask may be transferred to base 52 with an etch selective for semiconductor material of base 52 relative to material of layers 60 and 62. An etch is considered selective for a first material relative to a second material if the etch removes the first material at a faster rate than the second material, which may include, but is not limited to, etches which are 100 percent selective for the first material relative to the second.

The trenches are spaced from one another by intervening walls 65, 67 and 69. Such walls comprise semiconductor material of base 52.

The trenches are shown extending parallel to one another and along a first direction defined by a shown axis 71.

Referring to FIGS. 9-11, an electrically insulative material 72 is deposited within trenches 64, 66, 68 and 70, and over masking material 58. The trenches are shown in dashed-line view in the top view of FIG. 9 to indicate that the trenches are under insulative material 72.

The electrically insulative material may comprise any suitable composition or combination of compositions, and may, for example, comprise material traditionally utilized in shallow trench isolation. For instance, insulative material 72 may comprise, consist essentially of, or consist of silicon dioxide.

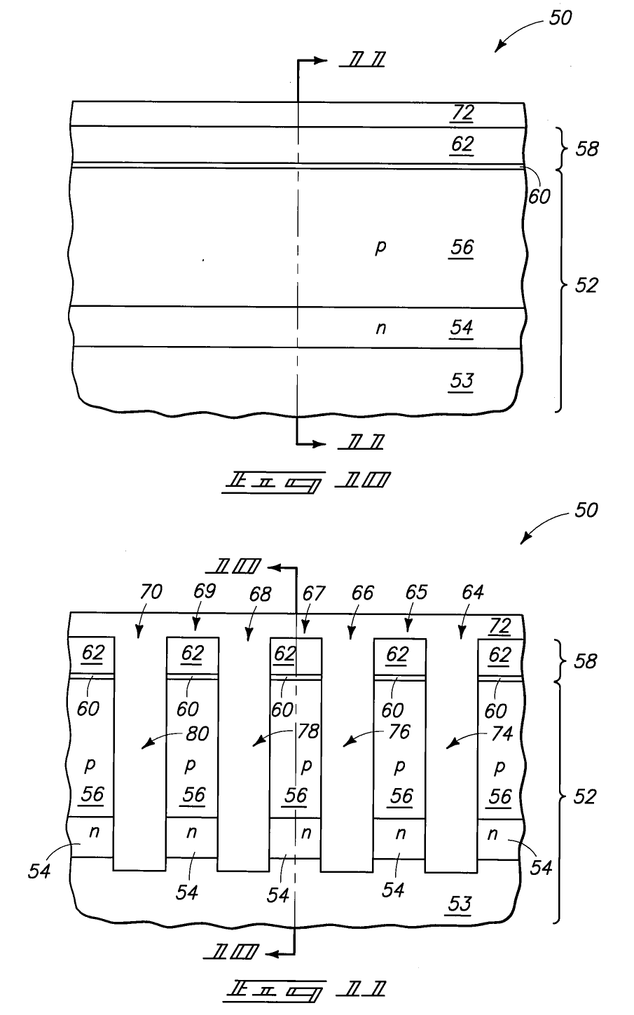

The insulative material 72 within trenches 64, 66, 68 and 70 may be considered to form partitions 74, 76, 78 and 80 (FIG. 11) which electrically isolate walls 65, 67 and 69 from one another. The partitions extend through doped region 54, and thus subdivide the region into a plurality of lines, (with such lines extending into and out of the page relative to the cross-sectional view of FIG. 11). In some embodiments, the region 54 forms a plurality of first electrodes for 0C1T memory unit cells, and in such embodiments the partitions may be considered to subdivide region 54 into a plurality of first electrode lines.

Referring to FIGS. 12-14, masking material 58 (FIGS. 9-11) is removed, and insulative material 72 is planarized down to an upper surface of semiconductor base 52. Subsequently, patterned masking material 82 is formed over an upper surface of construction 50. The patterned masking material forms strips 84, 86, 88 and 90 across the upper surface of construction 50, with such strips being in one-to-one correspondence with partitions 74, 76, 78 and 80. The strips leave the walls 65, 67 and 69 of semiconductor base 52 exposed between them.

The masking material 82 may comprise any suitable composition or combination of compositions, and may, for example, comprise a layer of silicon nitride over a layer of pad oxide. The masking material 82 may be patterned by forming a photolithographically patterned photoresist mask (not shown) over such material, transferring a pattern from the mask to material 82 with one or more etches, and then removing the photoresist mask.

Referring to FIGS. 15-17, a material 92 is formed within the gaps between the strips 84, 86, 88 and 90 of material 82. Material 92 may consist of one or more compositions which can be selectively etched relative to an outer surface of material 82. For instance, if the outer surface of material 82 consists of silicon nitride, material 92 may consist of silicon dioxide. Material 92 is shown planarized so that a planarized upper surface extends across materials 82 and 92. Such planarization may comprise chemical-mechanical polishing (CMP) utilizing an upper surface of material 82 as a polishing stop.

Referring to FIGS. 18-20, material 92 is patterned to form gaps 94 extending through material 92. Portions of the walls 65, 67 and 69 of semiconductor material 52 are exposed within such gaps. Such patterning may be accomplished by, for example, forming a photolithographically patterned photoresist mask over an upper surface of construction 50, transferring a pattern from the mask to material 92 with one or more etches, and then removing the photoresist mask.

Referring to FIGS. 21-23, materials 96 and 98 are formed within the gaps 94 (FIGS. 18-20). Material 96 may comprise the same composition as material 92, and may, for example, consist of silicon dioxide. Material 96 is shown formed within the gaps 94 (FIGS. 18-20) along edges of the gaps to narrow the gaps, and subsequently material 98 is formed within the narrowed gaps. Material 96 may be formed as an anisotropically etched liner within gaps 94. In other words, material 96 may be formed by depositing a layer of the material across an upper surface of construction 50, and then anisotropically etching the material to from liners along the edges of the gaps.

Material 98 comprises a different composition than materials 92 and 96, and may comprise a composition to which materials 92 and 96 may be selectively etched. For instance, if materials 92 and 96 consist of silicon dioxide, material 98 may consist of silicon nitride (or may comprise silicon nitride over a pad oxide). Materials 96 and 98 are shown having planarized upper surfaces.

Referring to FIGS. 24-26, materials 92 and 96 are removed to form gaps extending to semiconductor base 52, and subsequently such gaps are extended through doped region 56 and partially into doped region 54. Such removes segments of the semiconductor material-containing walls 65, 67 and 69 (FIGS. 21-23), and patterns the walls into pedestals (or mesas) 100, 102, 104, 106, 108, 110, 112, 114 and 116. More specifically, wall 65 is subdivided into pedestals 112, 114, and 116; wall 67 is subdivided into pedestals 106, 108 and 110; and wall 69 is subdivided into pedestals 100, 102 and 104.

The pedestals may be considered to be spaced from one another by first spaces (or gaps) 120, and to be spaced from the partitions 74, 76, 78 and 80 by second spaces (or gaps) 122. The first spaces 120 may be much wider than the second spaces 122, and may, for example, be at least five times wider than the second spaces in some embodiments.

Referring to FIGS. 27-29, dielectric material 124 and electrically conductive gate material 126 are formed within spaces 120 and 122 (FIGS. 24-26).

The dielectric material 124 may comprise any of the compositions discussed above with reference to the dielectric material 22 of FIG. 1. In some embodiments, the dielectric material 124 may be formed by thermally oxidizing surfaces of the pedestals. For instance, if semiconductor base 52 comprises silicon, the surfaces of the pedestals may be oxidized to form silicon dioxide. Additionally, or alternatively, at least some of dielectric material 124 may be deposited within spaces 120 and 122. For instance, if dielectric material 124 comprises a high-k material, such may be deposited within the spaces utilizing one or more of physical vapor deposition (PVD), chemical vapor deposition (CVD) and atomic layer deposition (ALD). The dielectric material 124 is formed to a thickness which partially fills spaces 120 and 122 to narrow the spaces; or in other words, is formed to line sidewalls of the pedestals.

Gate material 126 may comprise any of the compositions discussed above with reference to the gate material 24 of FIG. 1. The gate material may be deposited over dielectric material 124 within the narrowed spaces 120 and 122 utilizing any suitable processing, including, for example, one or more of PVD, CVD and ALD.

The gate material is formed to a height which extends along part of the upper regions 56 of the pedestals, but which does not extend along an entirety of the upper regions 56. In other words, the gate material is formed to be along lower segments of the regions 56, but not along uppermost segments of the regions 56. The gate material may be formed to the desired height by depositing the gate material only to such height. Alternatively, the gate material may be formed to the desired height in a two step process which comprises first depositing the gate material to fill the narrowed spaces, and then etching the gate material back to the desired height.

The dielectric material 124 and gate material 126 both entirely laterally surround portions of the upper regions 56 of the pedestals, as shown in the top view of FIG. 27. Although all of the pedestals are entirely laterally surrounded by gate material in the shown embodiment, in other embodiments some of the pedestals may be entirely laterally surrounded by the gate material while others are not entirely laterally surrounded by the gate material.

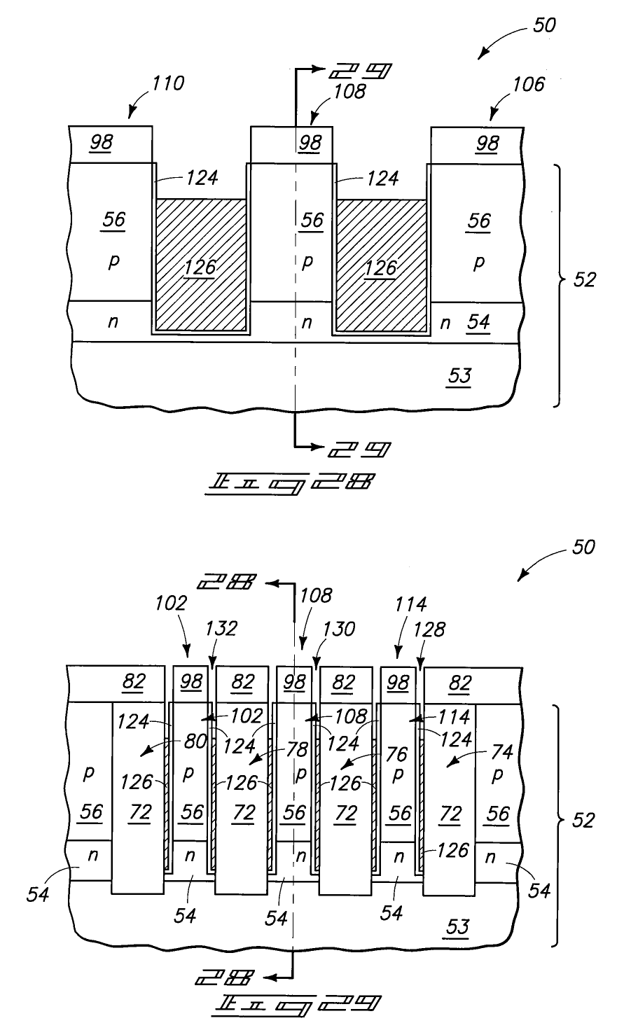

The gate material forms a plurality of wordlines 128, 130 and 132. The individual wordlines are elongated along the same axis 71 (FIG. 6) that the trenches were elongated along. The individual wordlines are each between a pair of the partitions 74, 76, 78 and 80 that were formed in such trenches (for instance, wordline 130 is between the partitions 76 and 78, as shown in FIG. 29).

Referring to FIGS. 30-32, masking material 98 (FIGS. 27-29) is removed, uppermost segments of the pedestals are counter-doped to form regions 134 at the tops of the pedestals that are the same conductivity type as region 54, insulative capping material 136 is formed over the gate material in the spaces, and bitlines 138, 140 and 142 are formed to be electrically coupled with the regions 134.

The uppermost segments of the pedestals may be counter-doped by providing a photolithographically-patterned mask (not shown) to protect regions which are not to be doped, implanting dopant into the uppermost segments, and then removing the photolithographically-patterned mask. In some embodiments, the counter-doping may occur at an earlier process step than that of FIGS. 30-32. For instance, in some embodiments the semiconductor base of FIGS. 3-5 may comprise three doped regions (54, 56 and 134) rather than the two shown regions. Also, in some embodiments the region 56 may be beneath an undoped region so that the doping to form region 134 is the first doping of the uppermost segment of base 52 rather than counter-doping of such uppermost segment. In some embodiments, one or both of the doped regions 54 and 56 may be omitted from the construction at the processing stage of FIGS. 3-5, and instead formed by an implant at a later processing stage.

The insulative capping material 136 may comprise any suitable composition or combination of compositions, and in some embodiments may comprise, consist essentially of, or consist of silicon dioxide.

The insulative capping material is patterned to form trenches extending therethrough where the bitlines will be formed. Such patterning may be accomplished by providing a photolithographically-patterned photoresist mask over a layer of the capping material, transferring a pattern from the mask to the underlying capping material, and then removing the mask.

The bitlines 138, 140 and 142 comprise bitline material 144. Such material may be any suitable electrically conductive composition or combination of electrically conductive compositions; and may, for example, comprise, consist essentially of, or consist of one or more of various metals, metal-containing compositions, and conductively-doped semiconductor materials.

The bitlines electrically couple with the conductively-doped regions 134 of the pedestals 100, 102, 104, 106, 108, 110, 112, 114 and 116. Each bitline is coupled to multiple pedestals, or in other words, the bitlines are coupled to the pedestals in a one-to-many relationship. The locations of the pedestals are shown in dashed-line view in the top view of FIG. 30 to indicate that the pedestals are beneath the bitlines. Also, the wordlines 128, 130 and 132 are shown in dashed-line view in the top view of FIG. 30 to indicate that the wordlines are underneath the bitlines. In the shown embodiment, the bitlines are parallel to one another and elongated along a direction substantially orthogonal to the direction of the wordlines. The term “substantially orthogonal” means that the bitlines are elongated along directions more orthogonal than not relative to the wordlines, and may include, but is not limited to, embodiments in which the bitlines are elongated along axes exactly orthogonal to the axes along which the wordlines are elongated.

Each of the shown pedestals 100, 102, 104, 106, 108, 110, 112, 114 and 116 corresponds to a 0C1T memory unit cell. The end regions 54 and 134 correspond to electrodes of the unit cells, and may correspond to a drain and source, respectively, of the unit cells. The central regions 56 comprise floating bodies of the unit cells. In the shown embodiment, the 0C1T memory unit cells extend vertically from the doped region 54 of the semiconductor base 52, and the floating bodies of such unit cells are entirely laterally surrounded by gate dielectric and wordlines. The illustrated unit cells comprise floating bodies majority doped to be p-type and electrodes majority doped to be n-type. In other embodiments, the doping of the floating bodies and electrodes may be reversed so that the floating bodies are n-type and the electrodes are p-type.

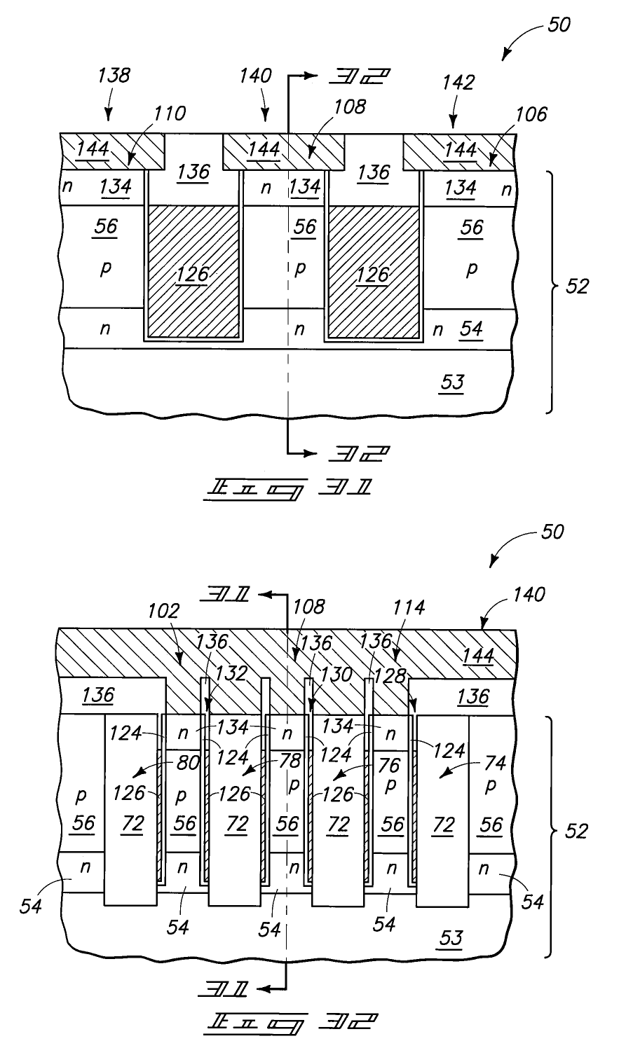

The pedestals 100, 102, 104, 106, 108, 110, 112, 114 and 116 may be considered to be an array of 0C1T memory unit cells. The array comprises three rows 160, 162 and 164 (labeled in FIG. 30) and three columns 170, 172 and 174 (labeled in FIG. 30). The wordlines 128, 130 and 132 extend along the rows, and the bitlines 138, 140 and 142 extend along the columns. The 0C1T memory unit cells along a row may be considered to be a bank of memory cells, and all of the unit cells of the bank share a common drain corresponding to the diffusion region 54. The partitions 74, 76, 78 and 80 (FIG. 32) isolate the common drain of one bank from the common drain of an adjacent bank. Accordingly, rows of unit cells share the same drain region as one another, but columns of unit cells do not share the same drain region.

The 0C1T memory unit cells coupled to the same wordline as one another may be considered to be a set of 0C1T memory cells; and similarly the 0C1T memory unit cells coupled to the same bitline as one another may also be considered to be a set of 0C1T memory cells. In some embodiments, the wordlines may be considered to be coupled with first sets of 0C1T memory cells and the bitlines may be considered to be coupled with second sets of the 0C1T memory cells. The first and second sets overlap so that individual unit cells belong both to a first set and to a second set, but differ from one another so that individual unit cells may be uniquely addressed by the combination of a wordline and a bitline.

Although the illustrated 0C1T memory array has only nine unit cells, the processing described herein may be utilized to form 0C1T memory arrays having hundreds, thousands, millions or more unit cells.

The memory described herein may be utilized in numerous electronic systems, including computers, cars, phones, cameras, etc.

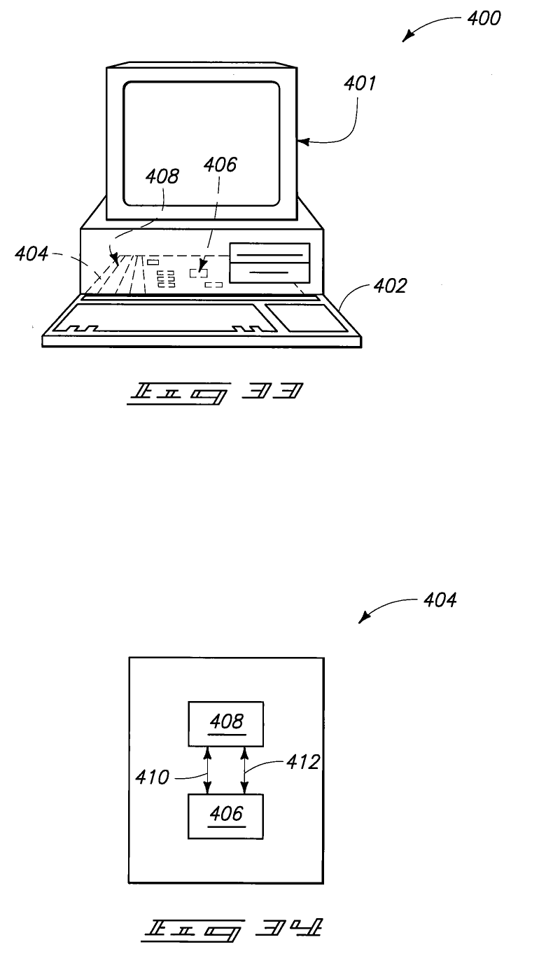

FIG. 33 illustrates an embodiment of a computer system 400 which may incorporate such memory. Computer system 400 includes a monitor 401 or other communication output device, a keyboard 402 or other communication input device, and a motherboard 404. Motherboard 404 may carry a microprocessor 406 or other data processing unit, and at least one memory device 408. Memory device 408 may comprise an array of memory cells, and such array may be coupled with addressing circuitry for accessing individual memory cells in the array. Further, the memory cell array may be coupled to a read circuit for reading data from the memory cells. The addressing and read circuitry may be utilized for conveying information between memory device 408 and processor 406. Such is illustrated in the block diagram of the motherboard 404 shown in FIG. 34. In such block diagram, the addressing circuitry is illustrated as 410 and the read circuitry is illustrated as 412.

Processor device 406 may correspond to a processor module, and associated memory utilized with the module may comprise 0C1T memory.

Memory device 408 may correspond to a memory module, and may comprise 0C1T memory. The memory device and processor may be fabricated to be on the same chip as one another, or may be on different chips relative to one another.

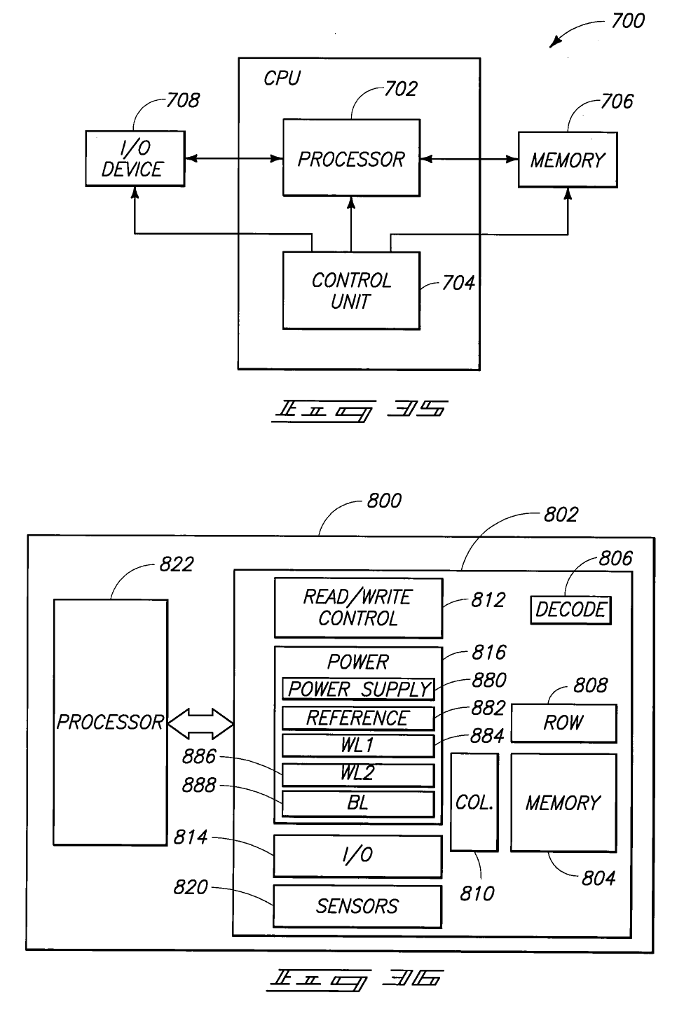

FIG. 35 illustrates a simplified block diagram of a high-level organization of an electronic system 700. System 700 may correspond to, for example, a computer system, a process control system, or any other system that employs a processor and associated memory. Electronic system 700 has functional elements, including a processor 702, a control unit 704, a memory device unit 706 and an input/output (I/O) device 708 (it is to be understood that the system may have a plurality of processors, control units, memory device units and/or I/O devices in various embodiments). Generally, electronic system 700 will have a native set of instructions that specify operations to be performed on data by the processor 702 and other interactions between the processor 702, the memory device unit 706 and the I/O device 708. The control unit 704 coordinates all operations of the processor 702, the memory device 706 and the I/O device 708 by continuously cycling through a set of operations that cause instructions to be fetched from the memory device 706 and executed. The memory device 706 may include 0C1T memory.

FIG. 36 is a simplified block diagram of an electronic system 800. The system 800 includes a memory device 802 that has an array of memory cells 804, address decoder 806, row access circuitry 808, column access circuitry 810, read/write control circuitry 812 for controlling operations, and input/output circuitry 814. The memory device 802 further includes power circuitry 816, and sensors 820, such as current sensors for determining whether a memory cell is in a low-threshold conducting state or in a high-threshold non-conducting state. The illustrated power circuitry 816 includes power supply circuitry 880, circuitry 882 for providing a reference voltage, circuitry 884 for providing a first wordline with pulses, circuitry 886 for providing a second wordline with pulses, and circuitry 888 for providing a bitline with pulses. The system 800 also includes a processor 822, or memory controller for memory accessing.

The memory device 802 receives control signals from the processor 822 over wiring or metallization lines. The memory device 802 is used to store data which is accessed via I/O lines. At least one of the processor 822 or memory device 802 may include 0C1T memory.

The various electronic systems may be fabricated in single-package processing units, or even on a single semiconductor chip, in order to reduce the communication time between the processor and the memory device(s).

The electronic systems may be used in memory modules, device drivers, power modules, communication modems, processor modules, and application-specific modules, and may include multilayer, multichip modules.

The electronic systems may be any of a broad range of systems, such as clocks, televisions, cell phones, personal computers, automobiles, industrial control systems, aircraft, etc.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A memory cell, comprising:
a projection of semiconductor material, the projection comprising a central region between a pair of end regions, the end regions being conductively-doped to a first dopant type and the central region being majority doped to a second dopant type opposite the first dopant type;
a wordline completely laterally surrounding the central region; and
no capacitor.

2. The memory cell of claim 1 wherein the first dopant type is n-type and the second dopant type is p-type.

3. The memory cell of claim 1 wherein the first dopant type is p-type and the second dopant type is n-type.

4. The memory cell of claim 1 wherein the wordline comprises one or more metals.

5. The memory cell of claim 1 wherein the wordline comprises one or more metal-containing compounds.

6. A memory bank, comprising:
a conductively-doped region at a first level of a semiconductor substrate; the conductively-doped region comprising a common first electrode of zero capacitor one transistor memory devices;
a plurality of floating body pillars extending vertically from the common first electrode;
a plurality of conductively-doped second electrode regions over and electrically coupled with the floating body pillars;
a wordline extending horizontally across the substrate, the wordline completely laterally surrounding the floating body pillars; and
a plurality of bitlines over the wordline, the bitlines being in one-to-one correspondence with the second electrode regions.

7. The memory bank of claim 6 wherein:
the common first electrode is majority n-type doped;
the second electrode regions are majority n-type doped; and
the floating body pillars comprise semiconductor material that is majority p-type doped.

8. The memory bank of claim 6 wherein:
the common first electrode is majority p-type doped;
the second electrode regions are majority p-type doped; and
the floating body pillars comprise semiconductor material that is majority n-type doped.

9. The memory bank of claim 6 wherein the wordline comprises one or more metals.

10. The memory bank of claim 6 wherein the wordline comprises one or more metal-containing compounds.

11. A memory array, comprising:
a conductively-doped first electrode region at a first level of a semiconductor substrate;
a plurality of semiconductor material mesas extending vertically from the first electrode region;
a plurality of conductively-doped second electrode regions within upper portions of the mesas;
a plurality of wordlines extending across the substrate, first sets of the mesas being coupled with individual of the wordlines, the individual mesas of at least some of the first sets being entirely laterally surrounded by the wordlines coupled to them and being floating bodies; and
a plurality of bitlines over the wordlines, the bitlines being electrically connected with the second electrode regions, second sets of the mesas being coupled with individual of the bitlines, the second sets overlapping the first sets but differing from the first sets so that at least some of the floating bodies are uniquely addressed by a combination of a word line and a bitline.

12. The memory array of claim 11 further comprising a plurality of electrically insulative partitions extending into the first electrode region and sub-dividing the first electrode region into first electrode lines; wherein individual wordlines connect rows of the mesas and wherein all of the mesas along a common row as one another extend from the same first electrode line.

13. The memory array of claim 11 wherein the bitlines extend substantially orthogonally to the wordlines.

14. An electronic system, comprising:
a processor; and
memory in data communication with the processor; the memory including integrated circuitry which contains:
first electrode lines spaced from one another by electrically insulative partitions, the first electrode lines being conductively-doped regions of a semiconductor material;
a plurality of semiconductor material mesas extending vertically from the first electrode lines; the mesas being in rows with all of the mesas along a common row as one another extending from the same first electrode line, and with mesas in different rows relative to one another extending from different first electrode lines relative to one another; the mesas comprising lower regions doped to majority dopant type opposite to a majority dopant type of the first electrode lines, and comprising upper regions doped to the same majority dopant type as the first electrode lines;
a plurality of wordlines extending across the substrate, first sets of the mesas being coupled with individual of the wordlines, the individual mesas of at least some of the first sets being entirely laterally surrounded by the wordlines coupled to them and being floating bodies; and
a plurality of bitlines over the wordlines, the bitlines being electrically connected with the upper regions of the mesas, second sets of the mesas being coupled with individual of the bitlines, the second sets overlapping the first sets but differing from the first sets so that at least some of the floating bodies are uniquely addressed by a combination of a wordline and a bitline.

15. The electronic system of claim 14 wherein the memory is on a common chip with the processor.

16. The electronic system of claim 14 wherein the memory is on a different chip than the processor.

17-35. (canceled)
